(19) United States
(12) Patent Application Publication
(10) Pub. No.: US 2026/0096019 A1
(43) Pub. Date: Apr. 2, 2026

(54) MANUFACTURING METHOD FOR A CIRCUIT BOARD AND CIRCUIT BOARD

(71) Applicant: JCET Management Co., LTD., Shanghai (CN)

(72) Inventors: Feifei WANG, Shanghai (CN); Jun XU, Shanghai (CN); Jingjing SHAN, Shanghai (CN); Shijian ZHAI, Shanghai (CN)

(73) Assignee: JCET Management Co., LTD., Shanghai (CN)

(21) Appl. No.: 19/323,740

(22) Filed: Sep. 9, 2025

(30) Foreign Application Priority Data
Sep. 27, 2024 (CN) 202411368786.2

(51) Int. Cl. H05K 1/02; H05K 1/03; H05K 1/09; H05K 1/11; H05K 3/00; H05K 3/10; H05K 3/22

(52) U.S. Cl. CPC H05K 1/0271; H05K 1/0306; H05K 1/09; H05K 1/113; H05K 3/0026; H05K 3/0044; H05K 3/107; H05K 3/225; H05K 2201/09627

(57) ABSTRACT

A manufacturing method for the circuit board includes the following steps: printing a board body on a carrier board using a 3D printing device, the board body having a hollow line channel in it, the line channel having openings located on an upper surface or/and a side surface of the board body; injecting a conductive material in a liquid state into the line channel inside the board body through at least one opening; the conductive material being in a solid state after cooling.

### CROSS-REFERENCE TO RELATED APPLICATIONS

This application claims the benefit of priority to Chinese Application No. 202411368786.2, filed Sep. 27, 2024, which is incorporated herein by reference in its entirety.

### TECHNICAL FIELD

The present disclosure relates to the field of semiconductor package, and specifically relates to a manufacturing method for a circuit board and a circuit board.

### BACKGROUND

In the field of semiconductor package, a circuit board is used to realize a stacked layout, and the circuit board includes a board body and a metal line arranged inside the board body, and the metal line has a portion exposed at the lower surface of the board body and a portion exposed at the upper surface of the board body.

### SUMMARY

A manufacturing method for a circuit board, it includes the following steps: printing a board body on a carrier board using a 3D printing device, the board body having a hollow line channel in it, an upper surface and/or a side surface of the board body having an opening connected with the line channel; injecting a conductive material in a liquid state into the line channel inside the board body through at least one opening; and the conductive material being in a solid state after cooling.

The board body is printed by a 3D printing device, which is not prone to deformation and fracture, and the conductive material in solid state is made by one-piece fusion casting, which is also not prone to deformation and fracture, and compared with the existing processing methods, the present disclosure effectively improves the problems of metal line layer delamination and circuit board stress warping in the circuit board. The present disclosure effectively improves the problems of traditional circuit board metal line layer delamination, circuit board stress warping. In the traditional manufacturing process of multi-layer metal lines of circuit board, multiple exposure, development, electroplating and other processes are required to be repeated many times, multiple alignments are required to ensure that the offset is within the tolerance, while the 3D printing method in the present disclosure only requires to be aligned once at the early stage of the manufacturing, and manufacturing efficiency is effectively improved. In the traditional manufacturing process, it is necessary to manufacture metal through-holes between the upper and lower metal line layers in the intermediary materials, but both laser holes and mechanical holes have their own manufacturing defects, such as laser holes cannot be perforated in thicker intermediary materials, and mechanical holes have a poorer integrity of shape, while the present disclosure adopts a 3D printing process to manufacture the board body, which can flexibly shape the internal conductive structure of the board body 2, making it manufacturable for through-hole manufacturing or other complex designs, i.e., the present disclosure can manufacture complex line channels 21, resulting in greater flexibility in the design of the metal line layers in the circuit board.

In some applications, the conductive material in liquid state is injected into the line channel inside the board body through multiple openings.

When the conductive material in liquid state is injected into the line channel in the board body through at least one opening, part of the heat is transferred to the board body after the conductive material in liquid state enters the line channel, which may easily lead to cooling and solidification of the conductive material, thus affecting the flow of the subsequent conductive material in liquid state, and resulting in the conductive material not being able to fill up the line channel. To address the above problem, when filling the line channel with the conductive material, the board body is preferably heated, so that the temperature of the board body is greater than or equal to the melting point of the conductive material and lower than the melting point of the board body.

In one embodiment of the present disclosure, when injecting the conductive material in liquid state into the line channel inside the board body through the opening, the board body is vibrated to accelerate the discharge of air in the line channel.

In one embodiment of the present disclosure, the conductive material filling up the line channel can be cooled by natural cooling, or it can be air-cooled by blowing air onto the surface of the board body.

In one embodiment of the present disclosure, it further includes the following steps:

After the conductive material is in a solid state, the carrier board is removed and the surface of the board is ground and planarized, so that the conductive material is exposed at the lower surface of the board body and the opening on the surface of the board body.

In one embodiment of the present disclosure, the line channel has a first area adjacent to or connected with the carrier board, the line channel has a second area at the opening, the conductive material forms a first pad in the first area, and the conductive material forms a second pad in the second area.

In one embodiment of the present disclosure, the melting point of the board body is greater than the melting point of the conductive material.

The melting point of the board body is greater than the melting point of the conductive material, which prevents the liquid conductive material, when injected into the line channel, from melting the board body or deforming the line channel.

In one embodiment of the present disclosure, the material of the board body is a material such as ceramic or synthetic glass.

In one embodiment of the present disclosure, the conductive material is metal.

In one embodiment of the present disclosure, the conductive material includes at least one of aluminum, nickel, tin, tungsten, platinum, copper, titanium, chromium, tantalum, gold, or silver.

In one embodiment of the present disclosure, before injecting the conductive material in a liquid state into the line channel inside the board body through at least one opening, it further comprises the following steps: removing burrs inside the line channel to make the inner wall of the line channel smooth.

In some applications, the line channel can specifically be cleaned using ultrasound, dry ice, laser and other cleaning methods.

The line channel can be cleaned by dry ice cleaning machine, the working principle of the dry ice cleaning machine is based on the physical properties of dry ice, and dry ice particles are sprayed into the line channel through the opening by high-pressure air, dry ice particles are solid and can gradually remove burrs through continuous collision, in addition, dry ice can directly transform from the solid state into a gaseous state, which is called sublimation, when dry ice particles come into contact with burrs, they will sublimate rapidly and form gaseous carbon dioxide. The sublimation of dry ice is accompanied by volume expansion, resulting in high pressure, the release of this high pressure can instantly knock off burrs from the inner wall surface of the line channel and carry them away with the airflow, so as to achieve the cleaning effect.

The line channel can be cleaned by ultrasonic waves, and burrs can be cleaned off through the “cavitation” effect. Ultrasonic cavitation effect refers to a dynamic process in which micro gas nuclei cavitation bubbles existing in liquids vibrate under the action of sound waves and grow and collapse when the sound pressure reaches a certain value. The cavitation effect generally includes three stages: the formation, growth, and violent collapse of cavitation bubbles. When a board body filled with liquid is connected with ultrasonic waves, tens of thousands of tiny bubbles, i.e., cavitation bubbles, are generated due to the vibration of the liquid. These bubbles grow in the negative pressure area formed by the longitudinal propagation of ultrasonic waves, and close rapidly in the positive pressure area, thus being compressed and stretched under alternating positive and negative pressures. At the moment when a bubble is compressed until it collapses, a huge instantaneous pressure is generated, generally up to tens of MPa to hundreds of MPa. When cleaning by means of the principle of ultrasonic waves, a specific operation method is as follows: injecting a liquid through the opening to fill the entire line channel, the liquid including water or cleaning solution; contacting the ultrasonic generator with the carrier board or board body, the ultrasonic generator is activated and is able to remove burrs from the inner wall of the line channel by means of a cavitation effect; injecting pressurized water through the opening to discharge the liquid in the line channel and the dropped burrs through other openings; and drying of the line channel, the drying method can be heating the board body, introducing a dry gas or a heated dry gas into the line channel through an opening.

In addition to cleaning by dry ice and ultrasonic cleaning, laser cleaning can also be used for cleaning, and burrs on the surface or shallow layers of the line channel can be cleaned by laser.

As shown in the figure, in addition to the aforementioned cleaning methods, burrs can also be removed by spraying metal sand into the line channel, the high-pressure gas drives the metal sand to move inside the line channel, and burrs can be knocked down through continuous collision of the metal sand with the inner side wall of the line channel, which finally makes the inner wall of the line channel smooth. After the cleaning is completed, burrs and metal sand in the line channel are blown out by introducing dry gas into the line channel. In the dry ice cleaning method, the dry ice is vaporized into carbon dioxide, while the cleaning method of spraying metal sand will have part of the metal sand still remaining in the line channel, and in order to prevent the residual metal sand from affecting the performance of the conductive material, it is preferred that the material of the metal sand is the same as the material of the conductive material, so that when injecting the conductive material in a liquid state into the line channel of the board body, it is possible to melt the residual metal sand to become part of the conductive material. In actual operation, as shown in the figure, the sandblasting gun can be pressed against one opening, the suction gun against another opening, and the other openings are blocked, the sandblasting gun is used to spray high-pressure gas and metal sand into the opening, and the suction gun is used to recover the metal sand and cleaned burrs.

In some applications, the solids recovered by the suction gun include metal sand and burrs, and the cost of metal sand is high, so it needs to be recycled. Considering that the melting point of metal sand is lower than that of burrs, it is possible to separate them by means of solid-liquid separation after heating. It is also possible to prepare a separation liquid with a density between metal sand and burrs, and separation can be rapidly carried out by putting the metal sand and the burr into the separation liquid, wherein one of them with a density greater than the separation liquid sinks to the bottom and the other with a density lower than the separation liquid floats up.

In one embodiment of the present disclosure, the line channel has a plurality of shunt segments arranged horizontally or inclined, at least two of the shunt segments being of different heights.

In one embodiment of the present disclosure, the conductive material in a liquid state is injected into the line channel by means of liquid pressure injection, vacuum pressurization, or the capillary principle.

The present disclosure also discloses a circuit board, manufactured and obtained by the manufacturing method for a circuit board as described above.

### BRIEF DESCRIPTION OF THE DRAWINGS

FIG. 1 is a schematic diagram of a board body after 3D printing on a carrier board;

FIG. 2 is a schematic diagram of the conductive material after it is injected into the line channel of the board body;

FIG. 3 is a schematic diagram of FIG. 2 after removal of the carrier board;

FIG. 4 is a schematic diagram of cleaning the line channel by injecting metal sand;

FIG. 5 is a schematic diagram after 3D printing a board body on the carrier board when the first area is not connected with the carrier board;

FIG. 6 is a schematic diagram of the line channel of FIG. 5 after injection of a conductive material;

FIG. 7 is a schematic diagram of FIG. 6 after removal of the carrier board;

FIG. 8 is a schematic diagram of the board body of FIG. 7 after grinding to expose the first pad;

FIG. 9 is a schematic diagram of a side surface of the line channel having an opening;

FIG. 10 is a schematic diagram after injection of conductive material and then removal of the carrier board in FIG. 9; and

FIG. 11 is a schematic diagram of the vibration mechanism cooperating with the board.

The reference numerals of the accompanying drawings are as follows:

1, carrier board; 2, board body; 21, line channel; 211, opening; 212, first area; 213, second area; 214, shunt section; 22, upper surface; 23, lower surface; 24, side surface; 3, conductive material; 31, first pad; 32, second pad; 33, third pad; 41, metal sand; 42, sandblasting gun; 43, suction gun; 5, vibration mechanism.

### DETAILED DESCRIPTION

In order to make the purposes, technical solutions, and advantages of the embodiments of the present disclosure more clearly, the technical solutions in the embodiments of the present disclosure will be described clearly and completely below in conjunction with the accompanying drawings in the embodiments of the present disclosure. Obviously, the described embodiments are a part of the embodiments of the present disclosure, rather than the entire embodiments. The components of embodiments of the present disclosure generally described and illustrated in the accompanying drawings herein may be arranged and designed in various different configurations.

In the description of the present disclosure, it should be noted that the terms “inside”, “outside”, etc. indicate orientations or positional relationships based on the orientations or positional relationships shown in the accompanying drawings, or the orientations or positional relationships commonly placed when using the products of the present disclosure, and it is only for the purpose of facilitating the description of the present disclosure and simplifying the description, and it is not intended to indicate or imply that the device or element referred to must have a particular orientation, be constructed and operated in a particular orientation, and therefore it is not to be construed as a limitation of the present disclosure. In addition, the terms “first”, “second”, etc. are used only to distinguish the description and are not to be understood as indicating or implying relative importance.

In the description of the present disclosure, it should also be noted that, unless otherwise clear regulations and limitations, the terms “setup” and “connection” should be broadly understood, e.g., it may be a fixed connection, a detachable connection, or a one-piece connection; it may be a direct connection, or an indirect connection through an intermediary dielectric. It may be a direct connection, an indirect connection through an intermediate medium, or a connection within two elements. For ordinary skilled in the art, the specific meanings of the above terms in the present disclosure may be understood in specific cases.

The present disclosure is described in detail below in conjunction with the respective accompanying drawings.

In the prior art, the circuit board is manufactured using a lamination method, and the circuit board is processed by means of one layer of metal after one layer of dielectric, and multiple alignments are required during the manufacturing process to ensure that the offset is within the tolerance, and the circuit board manufactured and obtained by this method is prone to having problems such as delamination and warping.

The present disclosure addresses the above problems and overcomes at least one deficiency, and proposes a manufacturing method for a circuit board and a circuit board.

The beneficial effects of the present disclosure are that: the board body is printed by the 3D printing device, and is not prone to deformation and fracture, and the solid conductive material is obtained by one-piece fusion casting, and is also not prone to deformation and fracture, and compared with the existing processing methods, the present disclosure effectively improves the problems of delamination and warping in the circuit board, in the traditional circuit board manufacturing process, multiple alignments are required to ensure that the offset is within the tolerance, while in the 3D printing method of the present disclosure, it only requires to be aligned once at the early stage of the manufacturing, and manufacturing efficiency is effectively improved; in the traditional production process, laser holes are not suitable for perforation in thicker dielectric materials, and the shape of mechanical holes is not as complete as laser holes, while the characteristic of 3D printing is that it can flexibly shape into any structure, which makes it manufacturable for through-hole manufacturing or other complex designs, and the present disclosure can manufacture complex line channels.

The present embodiment discloses a manufacturing method for a circuit board, which includes the following steps.

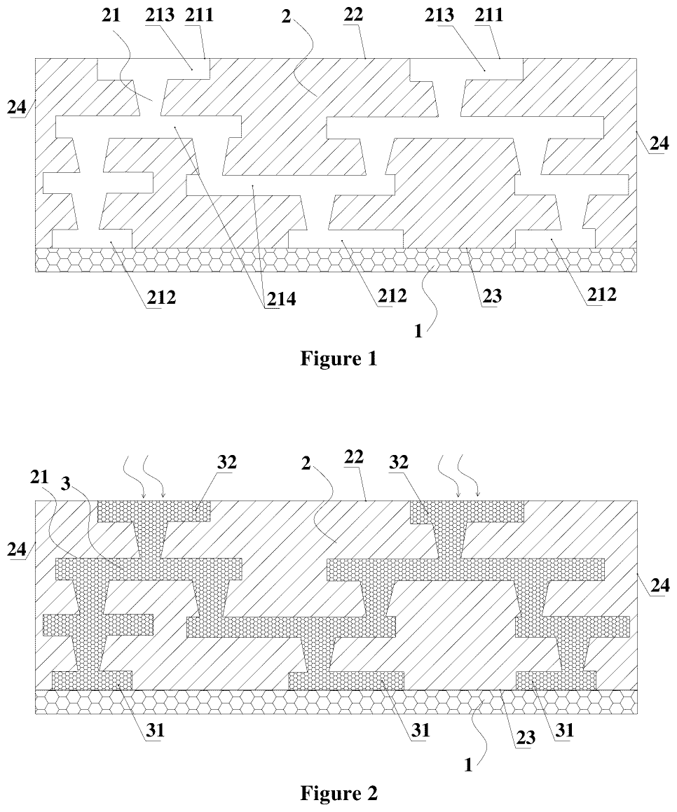

As shown in FIG. 1, a board body 2 is printed on a carrier board 1 using a 3D printing device, the board body 2 having a hollow line channel 21 inside it, and an upper surface 22 of the board body 2 has multiple openings 211 connected with the line channel 21.

As shown in FIG. 2, the conductive material 3 in a liquid state is injected into the line channels 21 inside the board body 2 through at least one opening 211, so that the conductive material 3 fills up all of the line channels 21 inside the board body 2.

The conductive material 3 is cooled and solidified, so that the conductive material 3 becomes a one-piece structure with the board body 2 in the line channels 21.

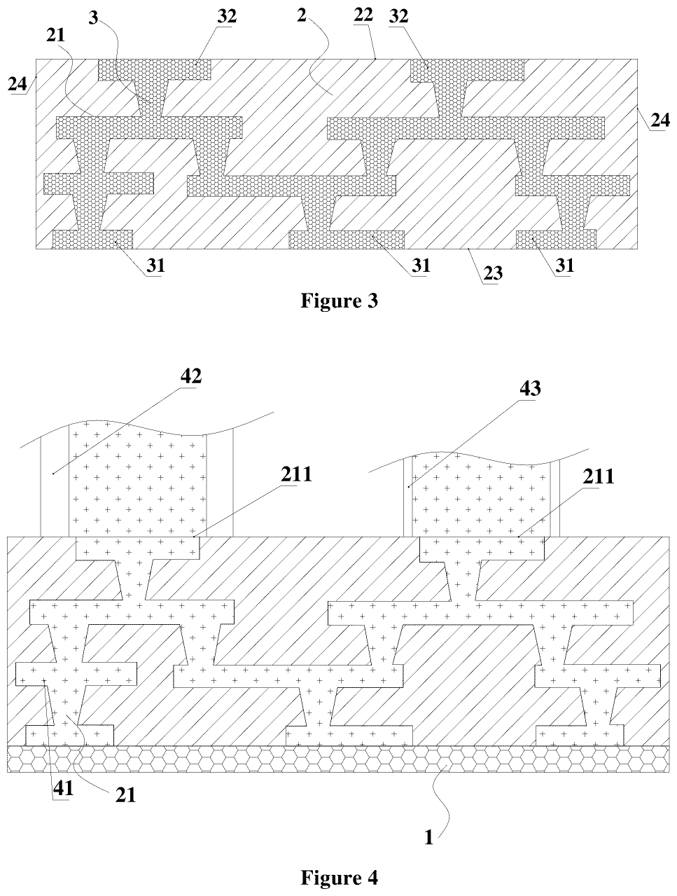

As shown in FIG. 3, after the conductive material 3 is in a solid state, the carrier board 1 is removed, and the upper and lower surfaces of the board body 2 are ground and planarized, so that the conductive material 3 exposes the upper surface of the board body 2 and the lower surface 23 of the board body 2 at the opening 211.

The board body 2 is printed by a 3D printing device, which is not prone to deformation and fracture, and the solid conductive material 3 is made by one-piece fusion casting, which is also not prone to deformation and fracture, and compared to the existing processing methods, the present disclosure effectively improves the problem of delamination of the metal line layer of the traditional circuit board, and stress warping of the circuit board. In the traditional process of manufacturing multi-layer metal lines of the circuit board, multiple exposure, development, electroplating and other processes are required to be repeated many times, and multiple alignments are required to ensure that the offset is within the tolerance, while in the 3D printing method of the present disclosure, it only requires to be aligned once at the early stage of the manufacturing, and manufacturing efficiency is effectively improved.

In the traditional manufacturing process, it is necessary to manufacture metal through-holes between the upper and lower metal line layers in the intermediary materials, but both laser holes and mechanical holes have their own manufacturing defects, such as laser holes cannot be perforated in thicker intermediary materials, and mechanical holes have a poorer integrity of shape, while the present disclosure adopts a 3D printing process to manufacture the board body, which can flexibly shape the internal conductive structure of the board body 2, making it manufacturable for through-hole manufacturing or other complex designs, i.e., the present disclosure can manufacture complex line channels 21, resulting in greater flexibility in the design of the metal line layers in the circuit board.

In some applications, the conductive material 3 in a liquid state is injected into the line channel 21 inside the board body 2 through multiple openings 211.

In the present embodiment, the melting point of the board body 2 is greater than the melting point of the conductive material 3. The melting point of the board body 2 is greater than the melting point of the conductive material 3, which prevents the conductive material 3 in a liquid state, when injected into the line channel 21, from melting the board body 2 or causing deformation of the line channel in the board body 2. The material of the board body 2 is a non-conductive material, which can be various, as long as it meets the product design requirements, and in the present embodiment, the material of the board body 2 is ceramic or synthetic glass. The conductive material 3 may be metallic or non-metallic, and in some embodiments, the conductive material 3 is metallic and may be one of or a combination of more of aluminum, nickel, tin, tungsten, platinum, copper, titanium, chromium, tantalum, gold, or silver.

The line channel 21 made by 3D printing will have burrs, and the burrs will affect the injection of the conductive material 3 and the working performance of the product, and in one of the embodiments, before injecting the conductive material 3 in liquid state into the line channel 21 inside the board body 2 through at least one opening 211, the following step is also included: removing the burrs inside the line channel 21, so as to make the inner wall of the line channel 21 smooth.

In practical application, the line channel 21 can specifically be cleaned using at least one cleaning method, such as ultrasound, dry ice, laser, etc. to remove burrs inside the line channel 21.

The line channel 21 can be cleaned by dry ice cleaning machine, the working principle of the dry ice cleaning machine is based on the physical properties of dry ice, and dry ice particles are sprayed into the line channel 21 through the opening 211 by high-pressure air, dry ice particles are solid and can gradually remove burrs through continuous collision; in addition, dry ice can directly transform from the solid state into a gaseous state, which is called sublimation, and when dry ice particles come into contact with burrs, they will sublimate rapidly and form gaseous carbon dioxide. The sublimation of dry ice is accompanied by volume expansion, resulting in high pressure. The release of this high pressure can instantly knock off burrs from the inner wall surface of the line channel 21 and carry them away with the airflow, so as to achieve the cleaning effect.

The line channel 21 can be cleaned by ultrasonic waves, and burrs can be cleaned off through the “cavitation” effect. Ultrasonic cavitation effect refers to a dynamic process in which micro gas nuclei cavitation bubbles existing in liquids vibrate under the action of sound waves and grow and collapse when the sound pressure reaches a certain value. The cavitation effect generally includes three stages: the formation, growth, and violent collapse of cavitation bubbles. When a board body filled with liquid is connected with ultrasonic waves, tens of thousands of tiny bubbles, i.e., cavitation bubbles, are generated due to the vibration of the liquid. These bubbles grow in the negative pressure area formed by the longitudinal propagation of ultrasonic waves, and close rapidly in the positive pressure area, thus being compressed and stretched under alternating positive and negative pressures. At the moment when a bubble is compressed until it collapses, a huge instantaneous pressure is generated, generally up to tens of MPa to hundreds of MPa. When a cleaning is performed by means of the principle of ultrasonic waves, the specific operation method is as follows.

A liquid is injected into the line channel 21 through the opening 211 so that the liquid fills the entire line channel 21, the liquid comprising water or cleaning fluid.

The ultrasonic generator is contacted with the carrier board 1 or the board body 2, and the ultrasonic generator is activated, which is capable of removing burrs from the inner wall of the line channel 21 by means of a cavitation effect.

Pressurized water is injected through one opening 211 to discharge the liquid in the line channel 21 and drop burrs out of the line channel 21 through other openings 211.

The line channel 21 is dried, which may be done by heating the board body 2, by passing a drying gas, or heated the drying gas through the openings 211 into the line channel 21.

In addition to cleaning by dry ice and ultrasonic cleaning, laser cleaning can also be used for cleaning, by laser, it is possible to clean burrs on the surface or shallow layer of the line channel 21.

As shown in FIG. 4, in addition to the aforementioned cleaning methods, burrs can also be removed by spraying metal sand 41 into the line channel 21, the high-pressure gas drives the metal sand 41 to move inside the line channel 21, and burrs can be knocked down through continuous collision of the metal sand 41 with the inner side wall of the line channel 21, which finally makes the inner wall of the line channel 21 smooth. After the cleaning is completed, burrs and metal sand 41 in the line channel 21 are blown out by introducing dry gas into the line channel 21. In the dry ice cleaning method, the dry ice is vaporized into carbon dioxide, and the cleaning method of spraying metal sand 41 will have part of the metal sand 41 still remaining in the line channel 21, in order to prevent the residual metal sand 41 from affecting the performance of the conductive material 3. In some embodiments, the material of the metal sand 41 is the same as the material of the conductive material 3, so that when injecting the conductive material 3 in a liquid state into the line channel 21 of the board body 2, it is possible to melt the residual metal sand 41 to become part of the conductive material 3. In actual operation, as shown in FIG. 4, the sandblasting gun 42 can be pressed against one opening 211, and the suction gun 43 pressed against another opening 211, and the other openings 211 are blocked, the sandblasting gun 42 is used to spray high-pressure gas and metal sand 41 into the opening, 211 and the suction gun is used to recover the metal sand 41 and cleaned burrs.

In some applications, the solids recovered by the suction gun include metal sand 41 and burrs, and the cost of metal sand is high and needs to be recycled. Considering that the melting point of metal sand 41 is lower than that of burrs, it is possible to separate them by means of solid-liquid separation after heating. It is also possible to prepare a separation liquid with a density between metal sand 41 and burrs, and separation can be rapidly carried out by putting the metal sand 41 and the burr into the separation liquid, wherein one of them with a density greater than the separation liquid sinks to the bottom and the other with a density lower than the separation liquid floats up.

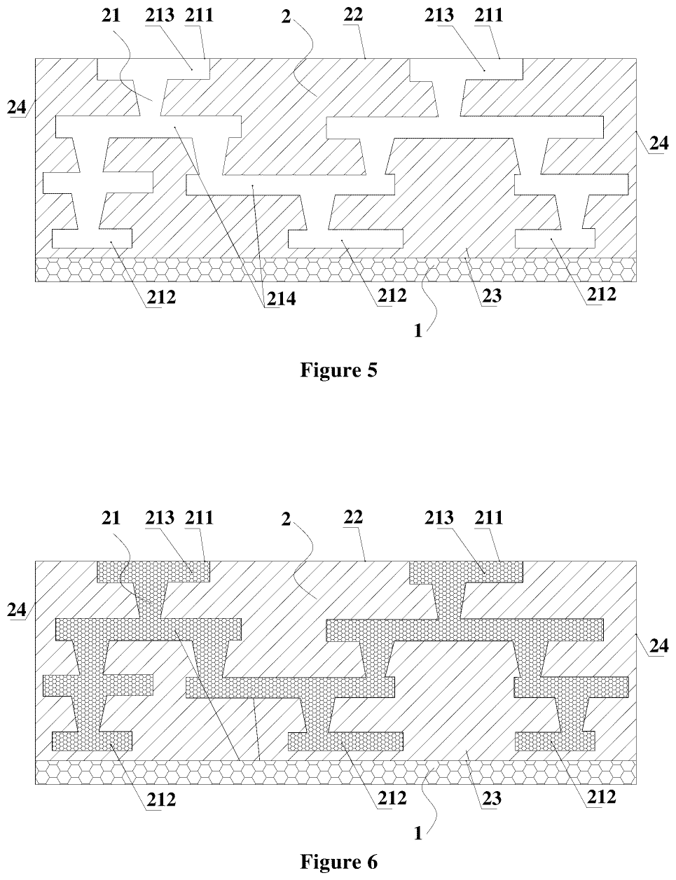

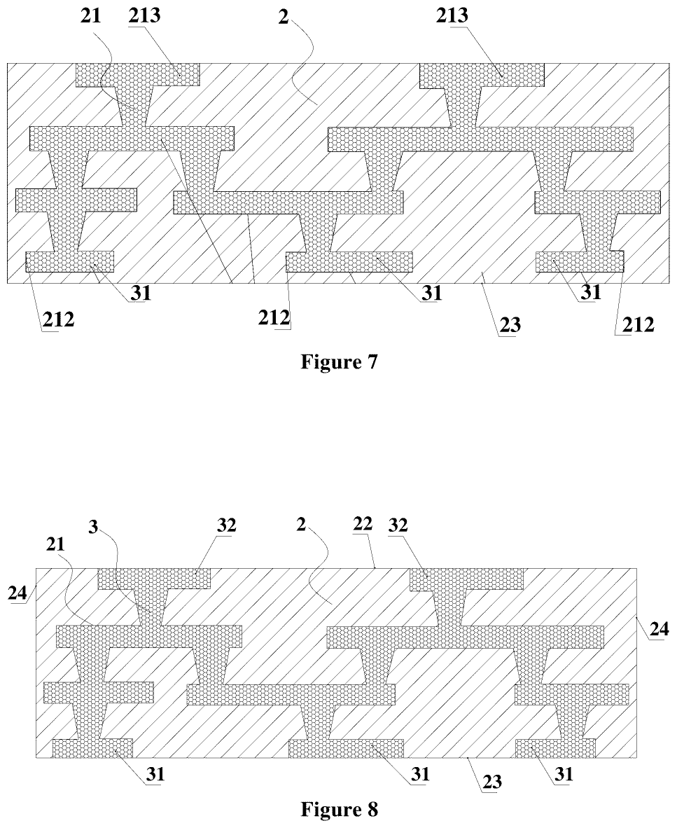

As shown in FIGS. 1 and 2, in the present embodiment, the line channel 21 has a first area 212 in contact with the carrier board 1, the line channel 21 has a second area 213 at the opening 211, the conductive material 3 forms a first pad 31 in the first area 212, and the conductive material 3 forms a second pad 32 in the second area 213. As shown in FIGS. 5 and 6, in other embodiments, the first area 212 of the line channel 21 may not be in direct contact with the carrier board 1, but is adjacent to the carrier board 1, and such a structure makes it possible that the second pad 32 will not be exposed after removal of the carrier board 1, as shown in FIG. 7, but the first area 212 can be exposed by grinding the lower surface 23 of the board body 2, as shown in FIG. 8. This processing method increases the thickness of the lower surface 23 of the board body 2 that needs to be ground, but compared to the structure of FIG. 1, it enables the lower surface 23 of the board body 2 to have more contact area with the carrier board 1, and the board body 2 and the carrier board 1 can be combined more reliably, which facilitates the operation of the subsequent processes.

When the conductive material 3 in liquid state is injected into the line channel 21 in the board body 2 through at least one opening 211, part of the heat is transferred to the board body after the conductive material 3 in liquid state enters the line channel 21, which may easily lead to cooling and solidification of the conductive material, thus affecting the flow of the subsequent conductive material 3 in liquid state, and resulting in the conductive material not being able to fill the line channel 21. To address the above problem, when filling the line channel 21 with the conductive material 3, the board body 2 is, in some embodiments, heated, so that the temperature of the board body 2 is greater than or equal to the melting point of the conductive material 3 and lower than the melting point of the board body 2.

In some applications, the conductive material 3 filling the line channel 21 can be cooled by natural cooling, or it can be air-cooled by blowing air onto the surface of the board body 2.

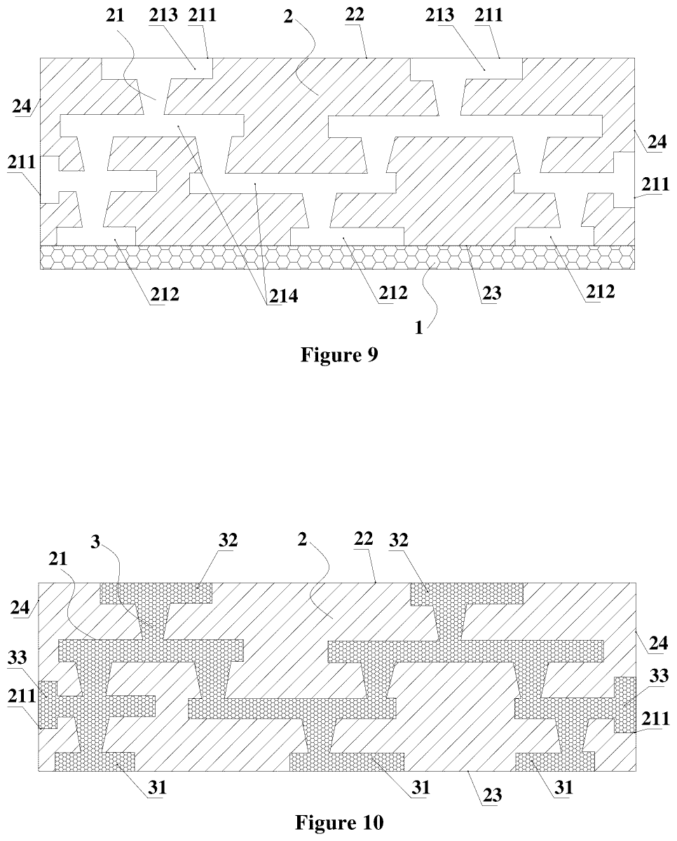

As shown in FIGS. 9 and 10, in another embodiment, in addition to the upper surface 22 of the board body, the side surface of the board body also has an opening 211 connected with the line channel 21. In such a configuration, the conductive material 3 can be exposed at the side surface 24 of the board body 2, so that it is possible to realize the lateral electrical connection of the board body 2; specifically, as shown in FIG. 10, on the opening 211 of the side surface of the board body 2, a third pad 33 is formed, through which other elements can be electrically connected. In another embodiment, the upper surface 22 of the board body 2 does not have opening 211, and the side surface 24 of the board body 2 has the openings 211 connected with the line channel 21.

As shown in FIG. 1, in one of embodiments, the line channel 21 has multiple shunt segments 214 arranged horizontally or inclined, and at least two of the shunt segments 214 have different heights. The present disclosure enables reliable manufacturing of the complex line channel 21 by means of 3D printing.

In one of embodiments, the liquid conductive material 3 is injected into the line channel 21 by vacuum pressurization, and the specific steps are as follows.

One or more openings 211 are sealingly connected with the evacuation tube, and other openings 211 are blocked, and the line channel 21 is evacuated by means of an evacuation device connected with the evacuation tube.

The conductive material 3 in a liquid state is injected into the line channel 21 inside the board body 2 through at least one opening 211 by means of injection equipment.

Evacuation is first performed, before the conductive material 3 in a liquid state is injected, which can prevent the generation of air bubbles and ensure the performance of the conductive material 3 after solidification.

In some applications, the conductive material 3 in a liquid state can also be injected into the line channel 21 by means of the capillary principle.

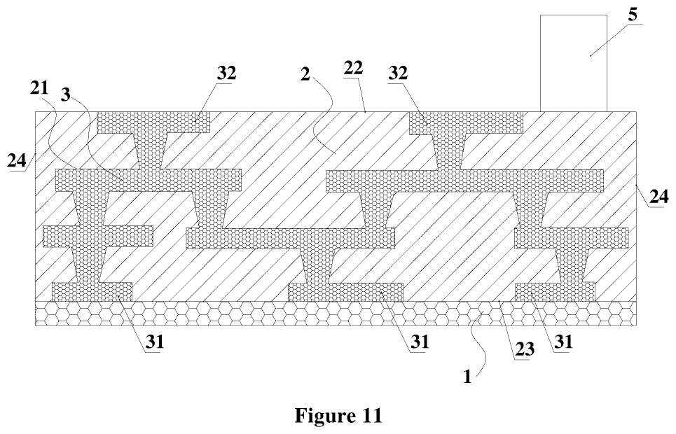

As shown in FIG. 11, in one of the embodiments, in order to prevent the presence of tiny air bubbles in the line channel 21, after injecting the conductive material 3, a vibration mechanism 5 is brought into contact with the board body 2, and the board body 2 is subjected to a high-frequency oscillation, so as to oscillate the tiny air bubbles out.

Shown in FIG. 3, FIG. 7, and FIG. 10 are circuit boards obtained by manufacturing using the method of different embodiments.

The above description is only some embodiments of the present disclosure and does not limit the scope of patent protection of the present disclosure, any equivalent structural transformation made using the content of the present disclosure description and drawings, directly or indirectly applied in other related technical fields, are also included in the scope of protection of the present disclosure.

What is claimed is:

1. A manufacturing method for a circuit board, comprising:
printing a board body on a carrier board using a 3D printing device, the board body having a hollow line channel therein, at least one of an upper surface or a side surface of the board body having an opening connected with the line channel; and
injecting a conductive material in a liquid state into the line channel inside the board body through at least one opening; and
cooling and solidifying the conductive material.

2. The manufacturing method for a circuit board according to claim 1, further comprising:
before injecting the conductive material in the liquid state into the line channel inside the board body through the at least one opening, removing burrs inside the line channel.

3. The manufacturing method for a circuit board according to claim 2, wherein the burrs are removed using at least one of ultrasound, dry ice, or laser.

4. The manufacturing method for the circuit board according to claim 1, wherein when injecting the conductive material in the liquid state into the line channel inside the board body through the at least one opening, the board body is heated so that a temperature of the board body is greater than or equal to a melting point of the conductive material and is lower than a melting point of the board body.

5. The manufacturing method for a circuit board according to claim 1, wherein when injecting the conductive material in the liquid state into the line channel inside the board body through the at least one opening, the board body is vibrated to accelerate discharge of air in the line channel.

6. The manufacturing method for a circuit board according to claim 1, further comprising:
after the conductive material is in a solid state, removing the carrier board and grinding and planarizing the at least one of the upper surface or the side surface of the board body so that the conductive material is exposed at a lower surface of the board body and an opening on the at least one of the upper surface or the side surface of the board body.

7. The manufacturing method for a circuit board according to claim 6, wherein the line channel has a first area adjacent to or connected with the carrier board, the line channel has a second area at the opening, the conductive material forms a first pad in the first area, and the conductive material forms a second pad in the second area.

8. The manufacturing method for a circuit board according to claim 1, wherein a melting point of the board body is greater than a melting point of the conductive material.

9. The manufacturing method for a circuit board according to claim 8, wherein a material of the board body is ceramic or synthetic glass.

10. The manufacturing method for a circuit board according to claim 8, wherein the conductive material is a metal.

11. The manufacturing method for a circuit board according to claim 10, wherein the conductive material comprises at least one of aluminum, nickel, tin, tungsten, platinum, copper, titanium, chromium, tantalum, gold, or silver.

12. The manufacturing method for a circuit board according to claim 1, wherein the line channel has a plurality of shunt segments arranged horizontally or inclined, at least two of the shunt segments being of different heights.

13. The manufacturing method for a circuit board according to claim 1, wherein the conductive material in the liquid state is injected into the line channel by at least one of liquid pressure injection, vacuum pressurization, or capillary principle.

14. A circuit board, comprising:
a board body having a hollow line channel therein, at least one of an upper surface or a side surface of the board body having an opening connected with the line channel; and
a conductive material in the line channel inside the board body.

15. The circuit board according to claim 14, wherein the conductive material forms a first pad in a first area of the line channel, and the conductive material forms a second pad in a second area of the line channel at the opening.

16. The circuit board according to claim 14, wherein a melting point of the board body is greater than a melting point of the conductive material.

17. The circuit board according to claim 16, wherein a material of the board body is ceramic or synthetic glass.

18. The circuit board according to claim 14, wherein the conductive material is a metal.

19. The circuit board according to claim 18, wherein the conductive material comprises at least one of aluminum, nickel, tin, tungsten, platinum, copper, titanium, chromium, tantalum, gold, or silver.

20. The circuit board according to claim 14, wherein the line channel has a plurality of shunt segments arranged horizontally or inclined, at least two of the shunt segments being of different heights.
